(19) United States
(12) Patent Application Publication
(10) Pub. No.: US 2026/0173850 A1
(43) Pub. Date: Jun. 18, 2026

(54) PACKAGE COMPRISING A SUBSTRATE WITH AN EMBEDDED PASSIVE DEVICE

(71) Applicant: QUALCOMM Incorporated, San Diego, CA (US)

(72) Inventors: Aniket PATIL, San Diego, CA (US); Joan Rey Villarba BUOT, Escondido, CA (US); Zhijie WANG, San Diego, CA (US)

(21) Appl. No.: 18/984,688

(22) Filed: Dec. 17, 2024

(51) Int. Cl. H01L 23/528; H01L 23/522

(52) U.S. Cl. CPC H10W 20/435; H10W 20/42; H10W 20/496

(57) ABSTRACT

A substrate comprising a core layer comprising a cavity; a passive device located at least partially in the cavity of the core layer, where the passive device comprises: a first plurality of pad interconnects configured to provide at least one electrical path for power; and a second plurality of pad interconnects configured to provide at least one electrical path for ground; at least one dielectric layer coupled to the core layer; and a plurality of interconnects located at least partially in the at least one dielectric layer.

### FIELD

Various features relate to packages and substrates.

### BACKGROUND

Packages can include a substrate, an integrated device and passive devices. The substrate may include a plurality of interconnects. Passive devices help in the proper operation of the package and any integrated devices that may be electrically coupled to passive devices. There is an ongoing need to provide smaller packages with improved performances, such as packages with improved passive device performance and/or improved performance in the power distribution network of the package.

### SUMMARY

Various features relate to packages and substrates.

One example provides a substrate comprising a core layer comprising a cavity; a passive device located at least partially in the cavity of the core layer, where the passive device comprises: a first plurality of pad interconnects configured to provide at least one electrical path for power; and a second plurality of pad interconnects configured to provide at least one electrical path for ground; at least one dielectric layer coupled to the core layer; and a plurality of interconnects located at least partially in the at least one dielectric layer.

Another example provides a package that includes a substrate and an integrated device coupled to the substrate through a plurality of solder interconnects. The substrate comprises a core layer comprising a cavity; a passive device located at least partially in the cavity of the core layer, where the passive device comprises: a first plurality of pad interconnects configured to provide at least one electrical path for power; and a second plurality of pad interconnects configured to provide at least one electrical path for ground; at least one dielectric layer coupled to the core layer; and a plurality of interconnects located at least partially in the at least one dielectric layer.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary profile view of a substrate with a passive device.

FIG. 2 illustrates an exemplary plan view of a substrate with a passive device.

FIG. 3 illustrates an exemplary profile view of a passive device.

FIG. 4 illustrates an exemplary profile view of a package that includes a substrate with a passive device.

FIG. 5 illustrates an exemplary profile view of a package that includes a substrate with a passive device.

FIGS. 6A-6F illustrate an exemplary sequence for fabricating a substrate with a passive device.

FIG. 7 illustrates an exemplary sequence for fabricating a substrate with a passive device.

FIG. 8 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a package that includes a substrate and an integrated device coupled to the substrate through a plurality of solder interconnects. The substrate comprises a core layer comprising a cavity; a passive device located at least partially in the cavity of the core layer, where the passive device comprises: a first plurality of pad interconnects configured to provide at least one electrical path for power; and a second plurality of pad interconnects configured to provide at least one electrical path for ground; at least one dielectric layer coupled to the core layer; and a plurality of interconnects located at least partially in the at least one dielectric layer. The passive device may include a deep trench capacitor. The configuration and/or arrangement of the plurality of pad interconnects may provide improved performance for the passive device, the integrated device, and/or the package.

### Exemplary Package with a Substrate Comprising a Passive Device

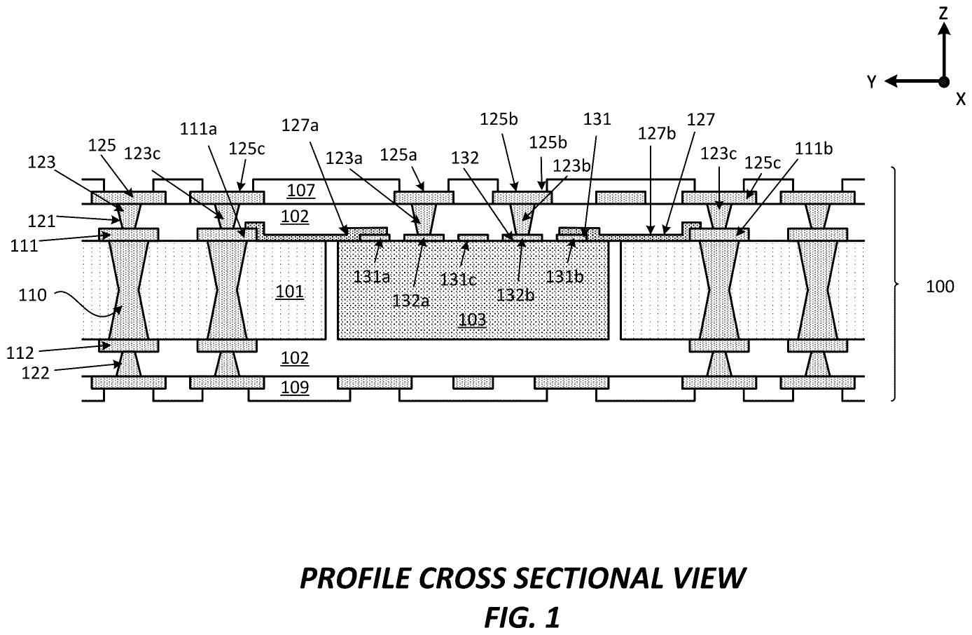

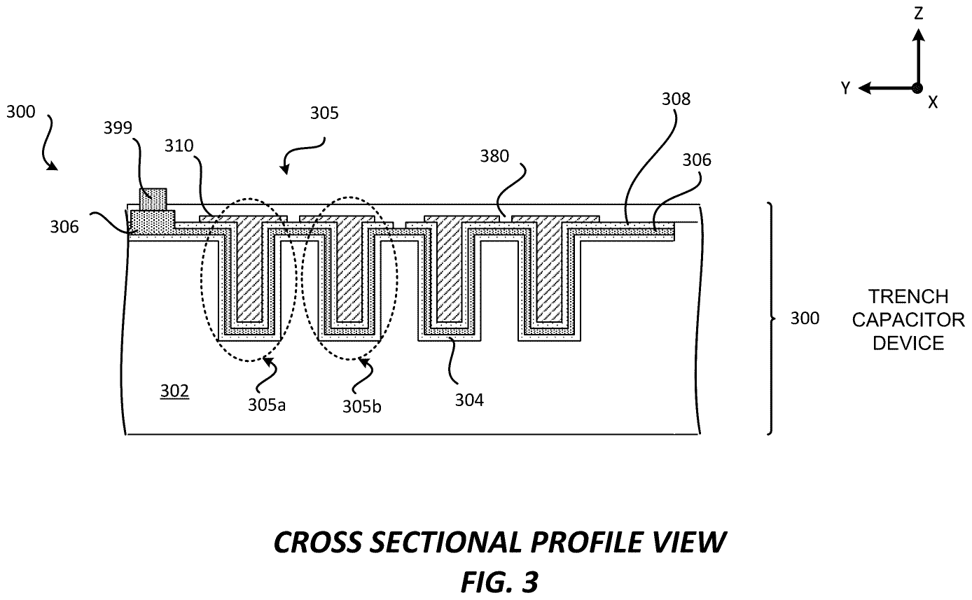

FIG. 1 illustrates a profile view of a substrate 100 that includes a passive device. The substrate 100 may be part of a package that includes an integrated device. The substrate 100 includes a core layer 101, at least one dielectric layer 102, a solder resist layer 107, a solder resist layer 109, a passive device 103, a plurality of via interconnects 120, a plurality of interconnects 121 and a plurality of interconnects 122. The passive device 103 may include a silicon capacitor, a deep trench capacitor (DTC) and/or a deep trench capacitor (DTC) device. A silicon capacitor may be a capacitor that is formed on a silicon substrate. An example of a passive device that may be implemented and/or embedded in a substrate, is illustrated and described below in at least FIG. 3 of the disclosure.

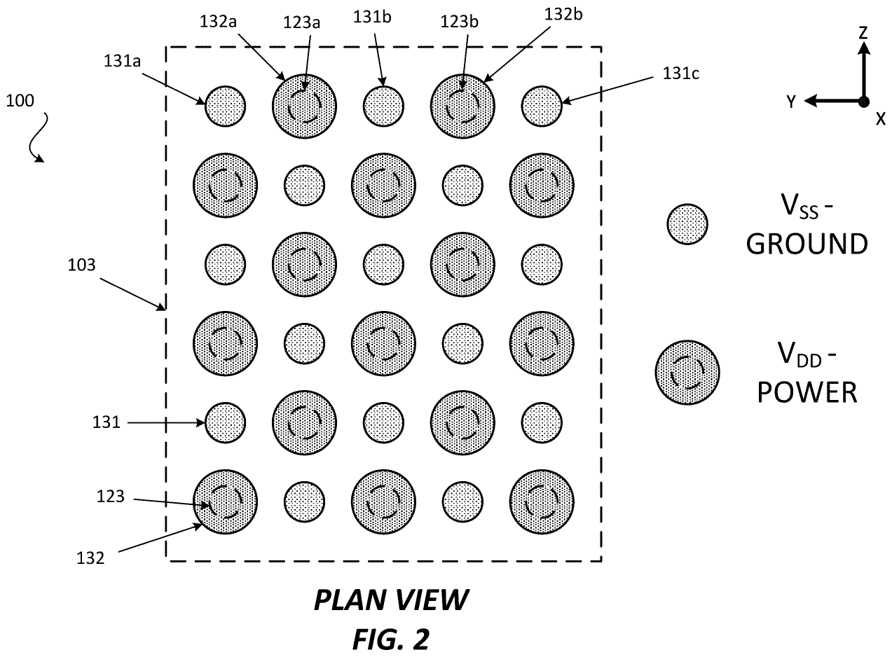

The core layer 101 includes a cavity that is at least partially filled and/or at least partially occupied by the passive device 103 and the at least one dielectric layer 102. The core layer 101 may laterally surround the passive device 103. The passive device 103 may include a plurality of pad interconnects 131 and a plurality of pad interconnects 132. In some implementations, pad interconnects from the plurality of pad interconnects 131 may include a first width and/or a first diameter. In some implementations, pad interconnects from the plurality of pad interconnects 132 may include a second width and/or a second diameter. The second width (and/or the second diameter) may be different from the first width (and/or the first diameter). In some implementations, the second width (and/or the second diameter) may be greater than the first width (and/or the first diameter). In some implementations, the second width (and/or the second diameter) may be less than the first width (and/or the first diameter). In some implementations, the plurality of pad interconnects 131 may be configured to provide at least one electrical path for ground, and the plurality of pad interconnects 132 may be configured to provide at least one electrical path for power. In some implementations, the plurality of pad interconnects 132 may be configured to provide at least one electrical path for ground, and the plurality of pad interconnects 131 may be configured to provide at least one electrical path for power. As will be further described below in at least FIG. 2, the plurality of pad interconnects 131 and the plurality of pad interconnects 132 may be arranged in an alternate manner. As will be further described below, the use, design and/or arrangement of the plurality of pad interconnects 131 and the plurality of pad interconnects 132 help provide more electrical paths for the passive device in the substrate and improved performance of the power distribution network.

In some implementations, the at least one dielectric layer 102 may include prepreg and/or Ajinomoto Build-up Film (ABF). However, the dielectric layer 102 may be a different type of dielectric. The solder resist layer 107 is coupled to a surface of the at least one dielectric layer 102. The solder resist layer 109 is coupled to another surface of the at least one dielectric layer 102. The core layer 101 may be a type of dielectric layer. The core layer 101 may be a type of a dielectric. The core layer 101 may include a different material and/or a same material as the at least one dielectric layer 102. The at least one dielectric layer 102 may represent one or more dielectric layers.

The plurality of via interconnects 110 are located in the core layer 101. The substrate 100 may include a plurality of interconnects 111 and a plurality of interconnects 112. The plurality of via interconnects 110 are coupled to the plurality of interconnects 111 and the plurality of interconnects 112. The plurality of via interconnects 110 may have different shapes for different implementations. The plurality of interconnects 111 may be coupled to a surface of the core layer 101. The plurality of interconnects 112 may be coupled to another surface of the core layer 101. The plurality of interconnects 111 and/or the plurality of interconnects 112 may be located at least partially in the at least one dielectric layer 102. The plurality of interconnects 121 are coupled to the plurality of interconnects 111. The plurality of interconnects 122 are coupled to the plurality of interconnects 112.

The substrate 100 also includes a plurality of interconnects 127. The plurality of interconnects 127 may be coupled to the plurality of interconnects 111 and the plurality of pad interconnects 131. The plurality of interconnects 127 may be located on a metal layer of the core layer 101. The plurality of interconnects 127 may include trace interconnects and via interconnects. The plurality of pad interconnects 131 may include a pad interconnect 131a, a pad interconnect 131b and a pad interconnect 131c. The plurality of interconnects 127 may include at least one interconnect 127a and at least one interconnect 127b. The plurality of interconnects 111 may include an interconnect 111a and an interconnect 111b. The at least one interconnect 127a is coupled to and touching the pad interconnect 131a and the interconnect 111a. The at least one interconnect 127b is coupled to and touching the pad interconnect 131a and the interconnect 111b. The pad interconnect 131a, the pad interconnect 131b, the interconnect 111a, the interconnect 111b, the interconnect 127a and the interconnect 127b may be considered to be located on a same metal layer of the substrate 100 (e.g., one a metal layer of a first surface of the core layer 101). The plurality of interconnects 127 may be coupled to the plurality of interconnects 111 and the plurality of pad interconnects 132.

The substrate 100 also includes a plurality of interconnects 123. The plurality of interconnects 123 may include via interconnects. The plurality of interconnects 121 may include a plurality of interconnects 125. The plurality of interconnects 125 may include a plurality of pad interconnects. The plurality of interconnects 123 may be coupled to the plurality of pad interconnects 132 and the plurality of interconnects 125. The plurality of interconnects 123 may be located vertically between pad interconnects from the plurality of interconnects 125 and the plurality of pad interconnects 132. The plurality of interconnects 123 may include an interconnect 123a and an interconnect 123b. The plurality of interconnects 125 may include an interconnect 125a and an interconnect 125b. The plurality of pad interconnects 132 include a pad interconnect 132a and a pad interconnect 132b. The interconnect 123a is coupled to the pad interconnect 132a and the interconnect 125a. The interconnect 123b is coupled to the pad interconnect 132b and the interconnect 125b. The plurality of interconnects 125 may be located on a different metal layer of the substrate 100 than the plurality of interconnects 111, the plurality of pad interconnects 131 and/or the plurality of pad interconnects 132.

FIG. 2 illustrates a plan view of the substrate 100 that includes the passive device 103. FIG. 2 illustrates an exemplary configuration and/or arrangement of pad interconnects for the passive device 103. The passive device 103 includes the plurality of pad interconnects 131 and the plurality of pad interconnects 132. Pad interconnects from the plurality of pad interconnects 132 are larger and/or wider (e.g., have a larger width and/or a larger diameter) than pad interconnects from the plurality of pad interconnects 131. The plurality of interconnects 123, which includes a plurality of via interconnects, are coupled to and touching the plurality of pad interconnects 132. In some implementations, no via interconnects from the substrate 100 is touching the plurality of pad interconnects 131. The plurality of pad interconnects 131 and the plurality of pad interconnects 132 may be arranged and/or configured in an alternate configuration. For example, a first row of pad interconnects may alternate between a pad interconnect from the plurality of pad interconnects 131 and a pad interconnect from the plurality of pad interconnects 132. For example, the first row of pad interconnects may include a pad interconnect 131a, a pad interconnect 132a, a pad interconnect 131b, a pad interconnect 132b and a pad interconnect 131c. In some implementations, a second row of pad interconnects may alternate between a pad interconnect from the plurality of pad interconnects 132 and a pad interconnect from the plurality of pad interconnects 131. In some implementations, a third row of pad interconnects may alternate between a pad interconnect from the plurality of pad interconnects 131 and a pad interconnect from the plurality of pad interconnects 132. Different implementations may arrange the plurality of pad interconnects 131 and/or the plurality of pad interconnects 132.

In some implementations, the plurality of pad interconnects 131 may be configured to provide at least one electrical path for ground, and the plurality of pad interconnects 132 may be configured to provide at least one electrical path for power. In some implementations, the plurality of pad interconnects 131 may be configured to provide at least one electrical path for power, and the plurality of pad interconnects 132 may be configured to provide at least one electrical path for ground.

In some implementations, the configuration of the plurality of pad interconnects 131 and the plurality of pad interconnects 132, how the passive device 103 is embedded in the substrate 100 and/or how the plurality of pad interconnects 131 and the plurality of pad interconnects 132 are connected in the substrate 100, help provide a substrate with an improved power distribution network profile. For example, using pad interconnects with different sizes and/or width, helps provide more pad interconnects in a given area, which can result in improved performance of the package, while still adhering to design rules. In some implementations, the plurality of pad interconnects 131 and/or the plurality of pad interconnects 132 may be coupled to and/or replaced with a plurality of post interconnects, as described in FIG. 3. For example, a plurality of post interconnects (e.g., a post interconnect 399) of FIG. 3 (which is described below), may replace and/or be coupled to the plurality pad interconnects 131 and/or the plurality of pad interconnects 132.

FIG. 3 illustrates a cross sectional profile view of a passive device 300 that is configured as a trench capacitor device. The passive device 300 may be an integrated passive device. The passive device 300 may represent any of the passive devices described in the disclosure. For example, the passive device 300 may represent the passive device(s) 103. The passive device 300 may be an integrated passive device that includes multiple trench capacitors (e.g., deep trench capacitors). The passive device 300 may be a means for trench capacitance. The passive device 300 includes a front side and a back side. The front side of the passive device 300 may include the plurality of trench capacitors.

The passive device 300 includes a passive device substrate 302 and a plurality of trench capacitors 305. A plurality of solder interconnects (not shown) may be coupled to the passive device 300. The passive device substrate 302 may include silicon (Si). The passive device substrate 302 may include a plurality of trenches and/or cavities over which capacitors may be formed.

The plurality of trench capacitors 305 includes a trench capacitor 305a and a trench capacitor 305b. In some implementations, the trench capacitor 305a and the trench capacitor 305b may be configured to be part of a same capacitor (e.g., first capacitor, first trench capacitor). In some implementations, the trench capacitor 305a and the trench capacitor 305b may be configured to be coupled to and/or part of a first power distribution network (PDN). The trench capacitor 305a and the trench capacitor 305b may be configured to be part of a first electrical path for a first power for a package. The trench capacitor 305a and the trench capacitor 305b may be configured to be coupled to integrated device(s).

As shown in FIG. 3, the passive device 300 includes the passive device substrate 302, an oxide layer 304, a first electrically conductive layer 306, a dielectric layer 308, a second electrically conductive layer 310 and a dielectric layer 380. The first electrically conductive layer 306 and/or the second electrically conductive layer 310 may include polysilicon. The oxide layer 304 and/or the dielectric layer 308 may include SiO₂ (e.g., low-pressure chemical vapor deposition (LPCVD) SiO₂) or Si₃N₄ (e.g., LPCVD Si₃N₄). Portions of the oxide layer 304, the first electrically conductive layer 306, the dielectric layer 308, and the second electrically conductive layer 310 may be located in trenches and/or cavities of the passive device substrate 302. The dielectric layer 380 may include silicon nitride. It is noted that a passive device substrate 302 may be considered to have a trench or a cavity, even if the trench or the cavity is filled with one or more materials.

The trench capacitor 305a (e.g., first trench capacitor, first capacitor, means for first trench capacitance) may be defined by (i) a first portion of the oxide layer 304, (ii) a first portion of the first electrically conductive layer 306, (iii) a first portion of the dielectric layer 308, and (iv) a first portion of the second electrically conductive layer 310 that are located in a trench (e.g., first trench) of the passive device substrate 302.

The trench capacitor 305b (e.g., second trench capacitor, second capacitor, means for second trench capacitance) may be defined by (i) a second portion of the oxide layer 304, (ii) a second portion of the first electrically conductive layer 306, (iii) a second portion of the dielectric layer 308, and (iv) a second portion of the second electrically conductive layer 310 that are located in a trench (e.g., second trench) of the passive device substrate 302. It is noted that trench capacitor 305b may be part of a same capacitor as the trench capacitor 305a. That is, the trench capacitor 305a and the trench capacitor 305b may be configured to be electrically coupled together to form a capacitor (e.g., first capacitor) with a greater capacitance. The passive device 300 may also optionally include a post interconnect 399 that is coupled to the first electrically conductive layer 306. The passive device may also include other post interconnects that are coupled to other second electrically conductive layer 310. The post interconnect 399 may be part of a plurality of post interconnects.

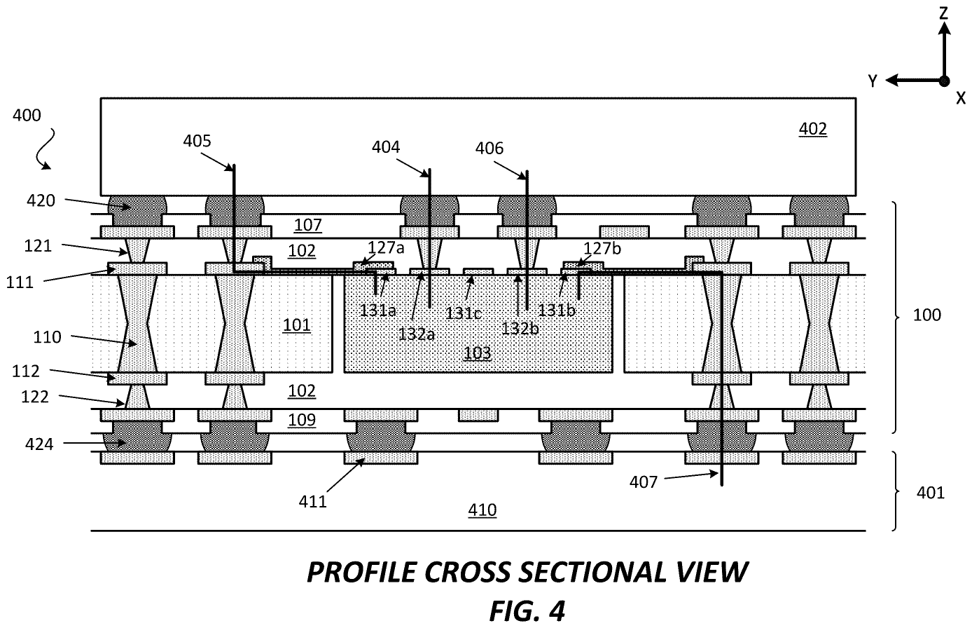

FIG. 4 illustrates a package 400 that includes a substrate 100 and an integrated device 402. The package 400 is coupled to a board 401 through a plurality of solder interconnects 424. The board 401 includes at least one board dielectric layer 410 and a plurality of board interconnects 411. The board 401 may include a printed circuit board (PCB). The plurality of solder interconnects 424 are coupled to the plurality of board interconnects 411 and the plurality of interconnects 122.

The integrated device 402 is coupled to the substrate 100 through a plurality of solder interconnects 420. The plurality of solder interconnects 420 may be coupled to the plurality of interconnects 121, including the plurality of interconnects 125.

FIG. 4 illustrates an electrical path 404, an electrical path 405, an electrical path 406 and an electrical path 407. In some implementations, the electrical path 404 and the electrical path 406 may be configured as electrical paths for power, and the electrical path 405 and the electrical path 407 may be configured as electrical paths for ground. In some implementations, the electrical path 404 and the electrical path 406 may be configured as electrical paths for ground, and the electrical path 405 and the electrical path 407 may be configured as electrical paths for power.

The electrical path 404 is an electrical path between the integrated device 402 and the passive device 103. The electrical path 404 may include (i) a solder interconnect from the plurality of solder interconnects 420, (ii) the interconnects 125a, (iii) the interconnects 123a, and (iv) the pad interconnects 132a.

The electrical path 406 is an electrical path between the integrated device 402 and the passive device 103. The electrical path 406 may include (i) another solder interconnect from the plurality of solder interconnects 420, (ii) the interconnects 125b, (iii) the interconnects 123b, and (iv) the pad interconnects 132b.

The electrical path 405 is an electrical path between the integrated device 402 and the passive device 103. The electrical path 405 may include (i) a solder interconnect from the plurality of solder interconnects 420, (ii) the interconnects 125c, (iii) the interconnects 123c, (iv) the interconnect 111a, (v) the interconnect 127a and (iv) the pad interconnects 131a.

The electrical path 407 is an electrical path between the passive device 103 and the board 401. The electrical path 407 may include (i) the pad interconnect 131a, (ii) the interconnect 127b, (iii) the interconnect a solder interconnect from the plurality of solder interconnects 420, (ii) the interconnects 125c, (iii) the interconnects 123c, (iv) the interconnect 127a and (iv) the pad interconnects 131a, (ii) the interconnect 127b, (iii) the interconnect 111b, (iv) an interconnect from the plurality of via interconnects 110, (v) a plurality of interconnects 122, (vi) a solder interconnect from the plurality of solder interconnects 424 and (vii) a board interconnect from the plurality of board interconnects 411.

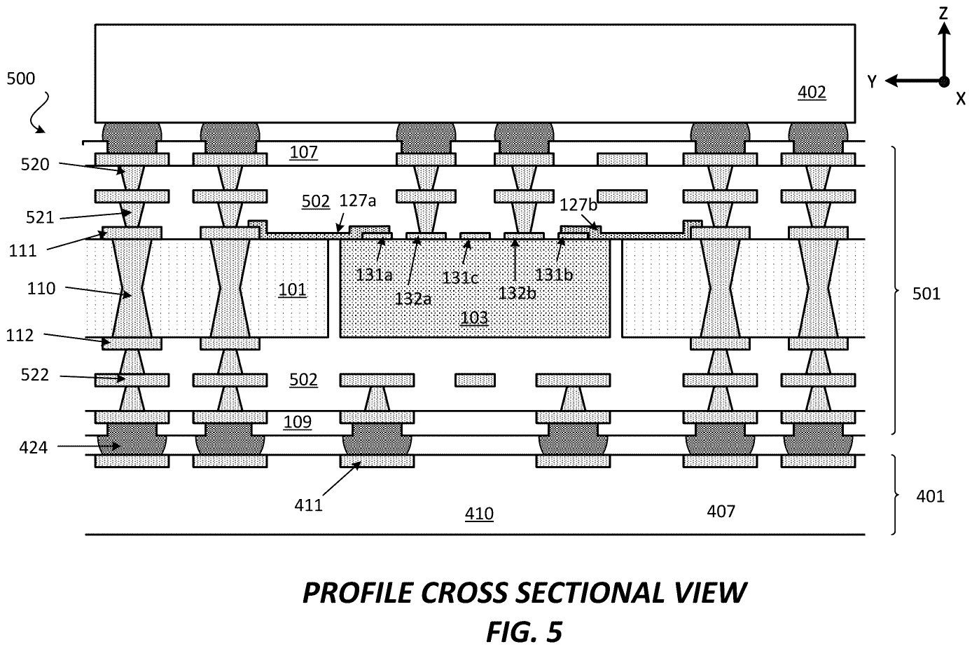

Different implementations may use different electrical for the package 400. Different implementations may also use different substrates with different number of metal layers. The package 400 of FIG. 4 includes a substrate 100 that includes 4 metal layers. FIG. 5 illustrates a package 500 that includes the integrated device 402 and the substrate 501. The substrate 501 is similar to the substrate 100. The passive device 103 is located and/or embedded in the substrate 501 in a similar manner as described in the substrate 100. The substrate 501 includes the core layer 101, the passive device 103, the at least one dielectric layer 502, the solder resist layer 107 and the solder resist layer 109. The substrate 501 is similar to the substrate 100. However, the substrate 501 includes 6 metal layers. Electrical paths to and/or from the passive device 103, the integrated device 402 and/or the board 401 for the package 500 of FIG. 5, may be similar to the electrical paths (e.g., 404, 405, 406 and 407) as described for the package 400 of FIG. 4.

An integrated device (e.g., 402) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc.). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 402) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap width between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 400, 500) may be implemented in a radio frequency (RF) package. The RF package may be a radio frequency front end (RFFE) package. A package (e.g., 400, 500) may be configured to provide Wireless Fidelity (WiFi) communication and/or cellular communication (e.g., 2G, 3G, 4G, 5G, 6G). The packages (e.g., 400, 500) may be configured to support Global System for Mobile (GSM) Communications, Universal Mobile Telecommunications System (UMTS), and/or Long-Term Evolution (LTE). The packages (e.g., 400, 500) may be configured to transmit and receive signals having different frequencies and/or communication protocols.

### Exemplary Sequence for Fabricating a Substrate with a Passive Device

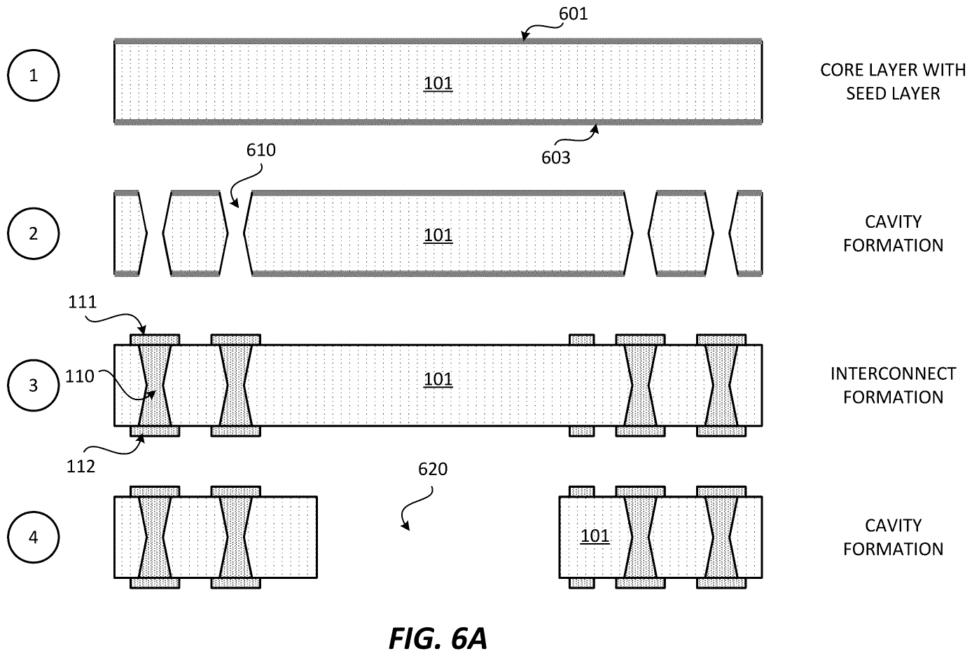

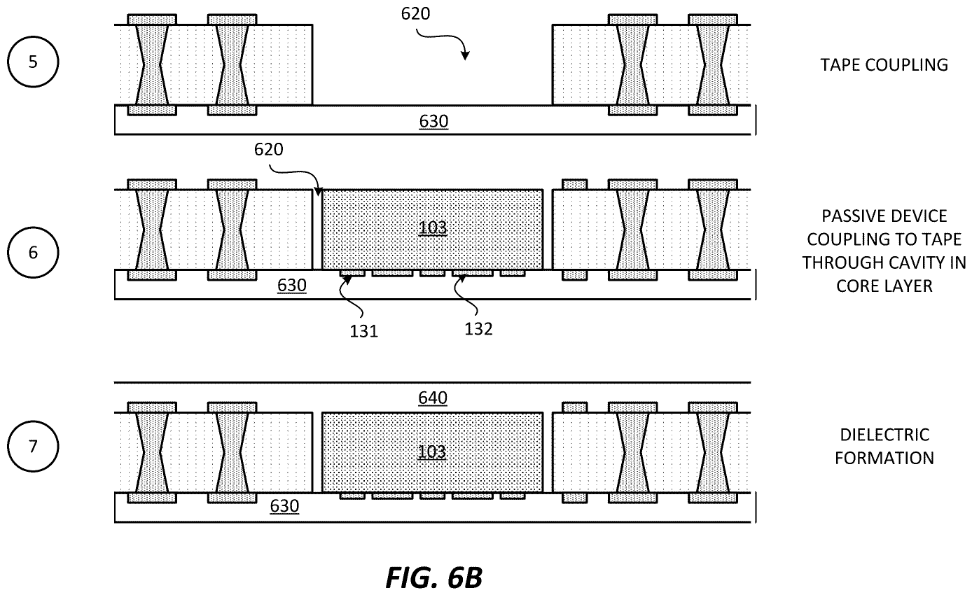

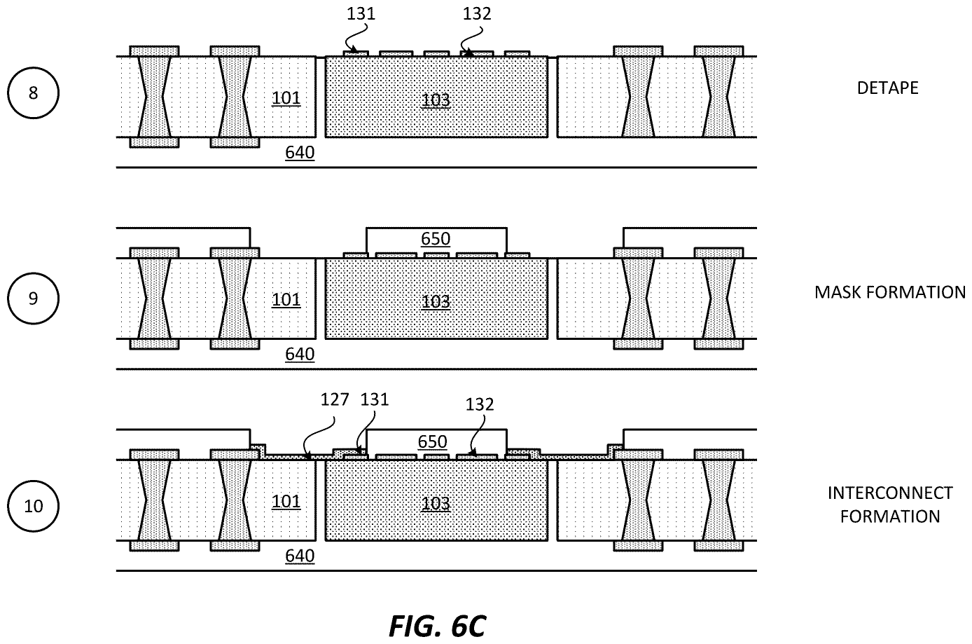

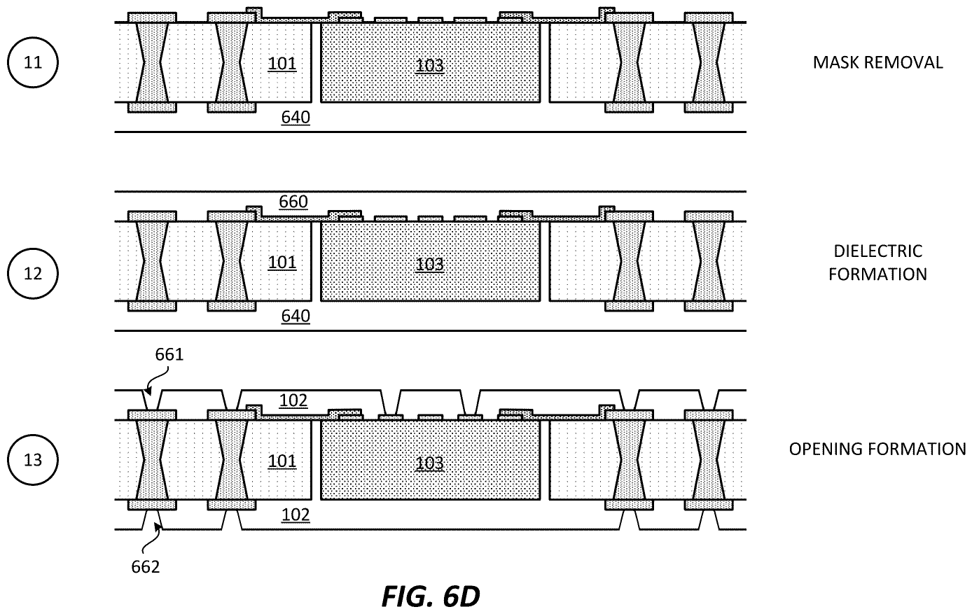

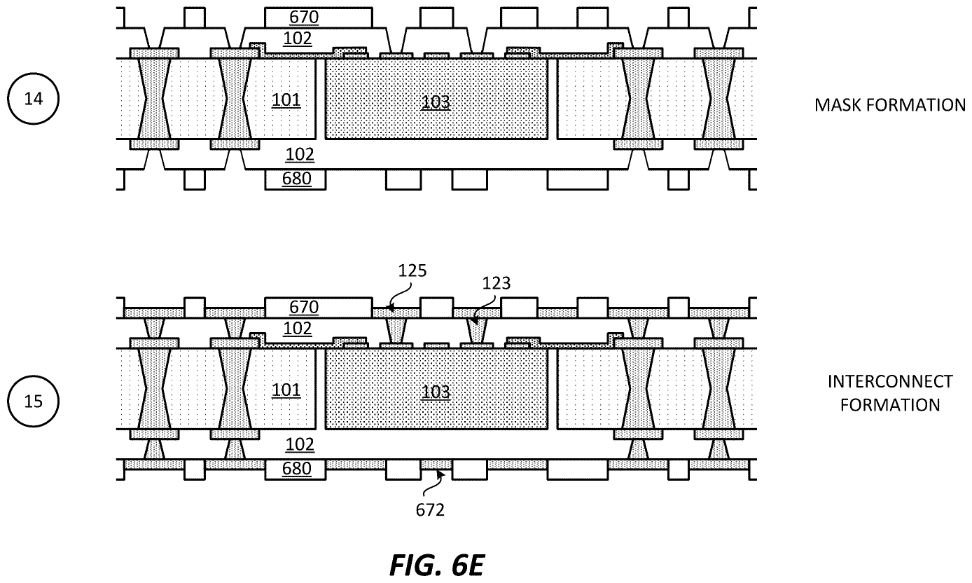

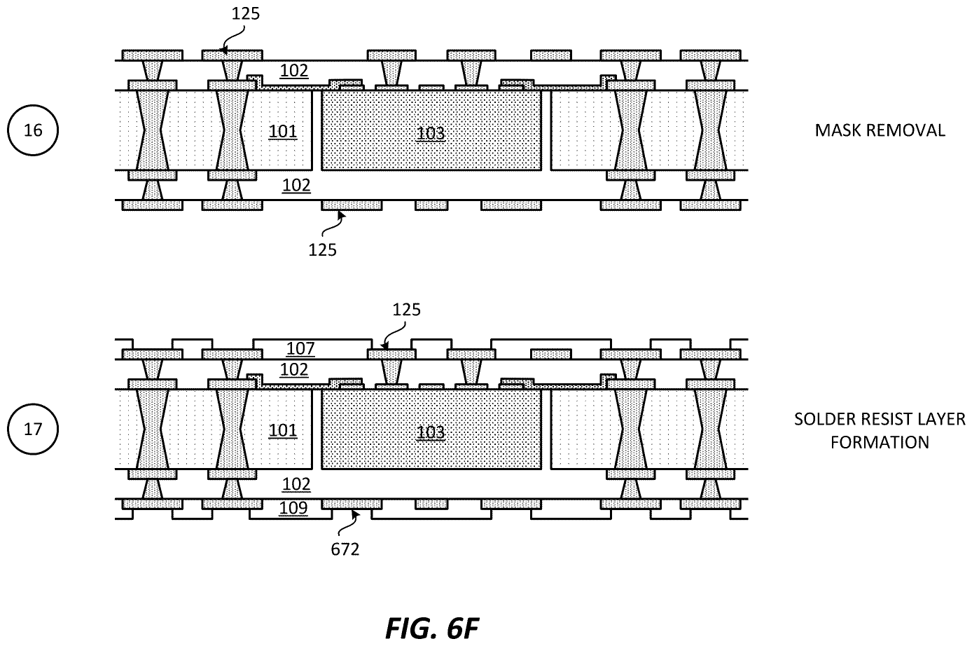

FIGS. 6A-6F illustrate an exemplary sequence for providing or fabricating a substrate with a passive device. In some implementations, the sequence of FIGS. 6A-6F may be used to provide or fabricate any of the substrates described in the disclosure. In some implementations, the sequence of FIGS. 6A-6F may be used to provide or fabricate the substrate 100 described in the disclosure.

It should be noted that the sequence of FIGS. 6A-6F may combine one or more stages in order to simplify and/or clarify the sequence for providing or fabricating a substrate. In some implementations, the order of the processes may be changed or modified. In some implementations, one or more of processes may be replaced or substituted without departing from the spirit of the disclosure. Different implementations may fabricate a substrate differently.

Stage 1, as shown in FIG. 6A, illustrates a state after a core layer 101 is provided. The core layer 101 may include a seed layer 601 coupled to a first surface of the core layer 101 and a seed layer 603 coupled to a second surface of the core layer 101. In some implementations, the core layer 101 may have a thickness in a range of about 40-205 micrometers.

Stage 2 illustrates a state after a plurality of cavities 610 are formed in the core layer 101. The plurality of cavities 610 may be formed through the seed layer 601 and the seed layer 603. A laser process (e.g., laser ablation) may be used to form the plurality of cavities 610. However, different implementations may use different processes to form the plurality of cavities 610. The plurality of cavities 610 may extend through the thickness of the core layer 101, the seed layer 601 and/or the seed layer 603.

Stage 3 illustrates a state after a plurality of via interconnects 110, a plurality of interconnects 111 and a plurality of interconnects 112. The plurality of via interconnects 110 may be formed in the plurality of cavities 610. The plurality of interconnects 111 may be formed and coupled to a first surface of the core layer 101. In some implementations, part of the seed layer 601 may be part of the plurality of interconnects 111. The plurality of interconnects 111 may be coupled to the plurality of via interconnects 110. The plurality of interconnects 112 may be formed and coupled to a second surface of the core layer 101. In some implementations, part of the seed layer 603 may be part of the plurality of interconnects 112. The plurality of interconnects 112 may be coupled to the plurality of via interconnects 110. A plating process and a patterning process may be used to form the plurality of via interconnects 110, the plurality of interconnects 111 and/or the plurality of interconnects 112.

Stage 4 illustrates a state after a cavity 620 is formed in the core layer 101. The cavity 620 may be formed through the core layer 101. A laser process (e.g., laser ablation) may be used to form the cavity 620. However, different implementations may use different processes to form the cavity 620. The cavity 620 may extend through the thickness of the core layer 101.

Stage 5, as shown in FIG. 6B, illustrates a state after the core layer 101 with the cavity 620 is coupled to a tape 630. The tape 630 may be a type of carrier. The tape 630 may include an adhesive. The tape 630 may be touching the plurality of interconnects 612 and/or the core layer 101.

Stage 6 illustrates a state after a passive device 103 that includes a plurality of pad interconnects 131 and a plurality of pad interconnects 132, is coupled to the tape 630. The passive device 103 is coupled to the tape 630 through the cavity 620 in the core layer 101. The passive device 103 is located at least partially in the cavity 620 of the core layer 101.

Stage 7 illustrates a state after a dielectric layer 640 is formed. The dielectric layer 640 fills at least part of the cavity 620 of the core layer 101. The dielectric layer 640 is coupled to the passive device 103 and the core layer 101. The dielectric layer 640 may be coupled to a second surface (e.g., bottom surface) of the core layer 101. A deposition process and/or a lamination process may be used to form the dielectric layer 640. In some implementations, the dielectric layer 640 may include a polymer. In some implementations, the dielectric layer 640 may include prepreg. In some implementations, the dielectric layer 640 may include die attach film.

Stage 8, as shown in FIG. 6C, illustrates a state after the tape 630 is decoupled from the core layer 101 and the passive device 103. The tape 630 may be detached and/or peeled off.

Stage 9 illustrates a state after a mask 650 is provided. The mask 650 may include openings. The mask 650 may be a dry film that is exposed and developed.

Stage 10 illustrates a state after the plurality of interconnects 127 are formed. The plurality of interconnects 127 may be coupled to the plurality of interconnects 111 and the plurality of pad interconnects 131. The plurality of interconnects 127 may be also be coupled to the plurality of interconnects 111 and the plurality of pad interconnects 132. A plating process may be used to form the plurality of interconnects 127.

Stage 11, as shown in FIG. 6D, illustrates a state after the mask 650 is removed.

Stage 12 illustrates a state after the dielectric layer 660 is provided and formed over the passive device 103 and a surface of the core layer 101. A deposition process and/or a lamination process may be used to form the dielectric layer 660.

Stage 13 illustrates a state after a plurality of cavities 661 and a plurality of cavities 662 are formed in the at least one dielectric layer 102. The at least one dielectric layer 102 may represent the dielectric layer 640 and/or the dielectric layer 660. A laser process (e.g., laser ablation) and/or a photo etching process may be used to form the plurality of cavities 661 and/or the plurality of cavities 662.

Stage 14, as shown in FIG. 6E, illustrates a state after a mask 670 and a mask 680 are provided on the at least one dielectric layer 102. The mask 670 and/or the mask 680 may include openings. The mask 670 and/or the mask 680 may be a dry film that is exposed and developed.

Stage 15, illustrates a state after a plurality of interconnects 125 and/or the plurality of interconnects 123 are formed and a plurality of interconnects 672 are formed. A plating process may be used to form the plurality of interconnects 123, the plurality of interconnects 125 and the plurality of interconnects 672.

Stage 16, as shown in FIG. 6F, illustrates a state after the mask 670 and the mask 680 are removed.

Stage 17 illustrates a state after the solder resist layer 107 and the solder resist layer 109 are formed and provided on the substrate.

### Exemplary Flow Diagram of a Method for Fabricating a Substrate with a Passive Device

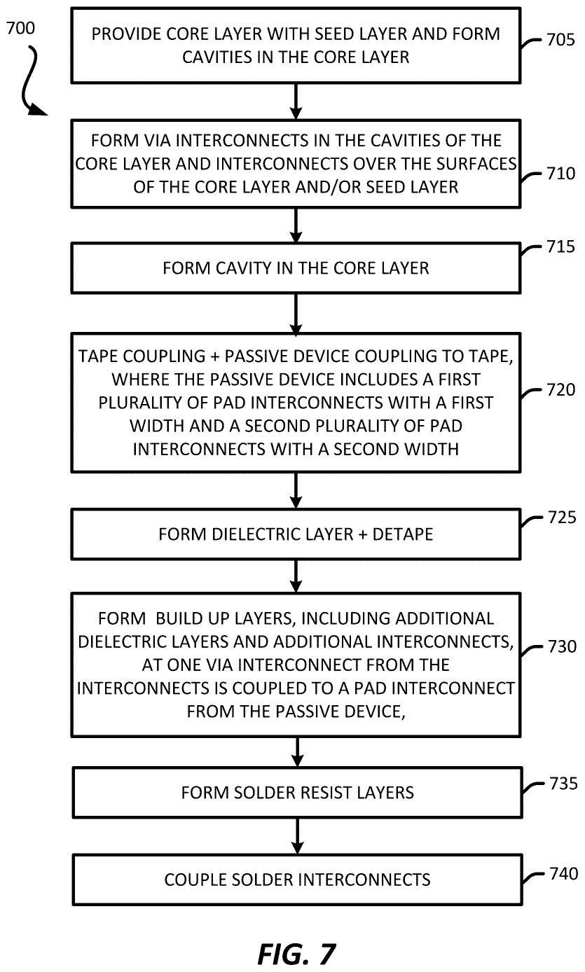

In some implementations, fabricating a substrate includes several processes. FIG. 9 illustrates an exemplary flow diagram of a method 700 for providing or fabricating a substrate with a passive device. In some implementations, the method 700 of FIG. 7 may be used to provide or fabricate the substrate 100.

It should be noted that the method 700 of FIG. 7 may combine one or more processes in order to simplify and/or clarify the method for providing or fabricating a substrate. In some implementations, the order of the processes may be changed or modified.

The method provides (at 705) a core layer with seed layers and forms cavities in the core layer through the seed layer. Stage 1 of FIG. 6A, illustrates and describes an example of a state after a core layer 101 is provided. The core layer 101 may include a seed layer 601 coupled to a first surface of the core layer 101 and a seed layer 603 coupled to a second surface of the core layer 101.

Stage 2 of FIG. 6A, illustrates and describes an example of a state after a plurality of cavities 610 are formed in the core layer 101. The plurality of cavities 610 may be formed through the seed layer 601 and the seed layer 603. A laser process (e.g., laser ablation) may be used to form the plurality of cavities 610. However, different implementations may use different processes to form the plurality of cavities 610. The plurality of cavities 610 may extend through the thickness of the core layer 101, the seed layer 801 and/or the seed layer 603.

The method forms (at 710) via interconnects in the core layer and interconnects on surfaces of the core layer. Stage 3 of FIG. 6B, illustrates and describes an example of a state after a plurality of via interconnects 110, a plurality of interconnects 111 and a plurality of interconnects 112. The plurality of via interconnects 110 may be formed in the plurality of cavities 610. The plurality of interconnects 111 may be formed and coupled to a first surface of the core layer 101. In some implementations, part of the seed layer 601 may be part of the plurality of interconnects 111. The plurality of interconnects 111 may be coupled to the plurality of via interconnects 110. The plurality of interconnects 112 may be formed and coupled to a second surface of the core layer 101. In some implementations, part of the seed layer 603 may be part of the plurality of interconnects 112. The plurality of interconnects 112 may be coupled to the plurality of via interconnects 110. A plating process and a patterning process may be used to form the plurality of via interconnects 110, the plurality of interconnects 111 and/or the plurality of interconnects 112.

The method forms (at 715) a cavity in the core layer. Stage 4 of FIG. 6A, illustrates and describes an example of a state after a cavity 620 is formed in the core layer 101. The cavity 620 may be formed through the core layer 101. A laser process (e.g., laser ablation) may be used to form the cavity 620. However, different implementations may use different processes to form the cavity 620. The cavity 620 may extend through the thickness of the core layer 101.

The method couples (at 720) the core layer to a tape and couples (at 720) the passive device to the tape. Stage 5 of FIG. 6B, illustrates and describes an example of a state after the core layer 101 with the cavity 620 is coupled to a tape 630. The tape 630 may be a type of carrier. The tape 630 may include an adhesive. The tape 630 may be touching the plurality of interconnects 612 and/or the core layer 101.

Stage 6 of FIG. 6B, illustrates and describes an example of a state after a passive device 103 that includes a plurality of pad interconnects 131 and a plurality of pad interconnects 132, is coupled to the tape 630. The passive device 103 is coupled to the tape 630 through the cavity 620 in the core layer 101. The passive device 103 is located at least partially in the cavity 620 of the core layer 101.

The method forms (at 725) at least one dielectric layer over the passive device. Stage 7 of FIG. 6B, illustrates and describes an example of a state after a dielectric layer 640 is formed. The dielectric layer 640 fills at least part of the cavity 620 of the core layer 101. The dielectric layer 640 is coupled to the passive device 103 and the core layer 101. The dielectric layer 640 may be coupled to a second surface (e.g., bottom surface) of the core layer 101. A deposition process and/or a lamination process may be used to form the dielectric layer 640. In some implementations, the dielectric layer 640 may include a polymer. In some implementations, the dielectric layer 640 may include prepreg. In some implementations, the dielectric layer 640 may include die attach film.

The method also decouples (at 725) the tape from core layer. Stage 8 of FIG. 6C, illustrates and describes an example of a state after the tape 630 is decoupled from the core layer 101 and the passive device 103. The tape 630 may be detached and/or peeled off.

The method forms (at 730) additional build up layers for the substrate, including additional dielectric layers and additional interconnects for the substrate. Stage 9 illustrates a state after a mask 650 is provided. The mask 650 may include openings. The mask 650 may be a dry film that is exposed and developed. Stage 10 of FIG. 6D through stage 16 of FIG. 6F, illustrate and describes an example of forming additional interconnects for the substrate.

Stage 10 of FIG. 6C, illustrates and describes an example of a state after the plurality of interconnects 127 are formed. The plurality of interconnects 127 may be coupled to the plurality of interconnects 111 and the plurality of pad interconnects 131. The plurality of interconnects 127 may be coupled to the plurality of interconnects 111 and the plurality of pad interconnects 132. A plating process may be used to form the plurality of interconnects 127.

Stage 11 of FIG. 6D, illustrates and describes an example of a state after the mask 650 is removed.

Stage 12 of FIG. 6D, illustrates and describes an example of a state after the dielectric layer 660 is provided and formed over the passive device 103 and a surface of the core layer 101. A deposition process and/or a lamination process may be used to form the dielectric layer 660.

Stage 13 of FIG. 6D, illustrates and describes an example of a state after a plurality of cavities 661 and a plurality of cavities 662 are formed in the at least one dielectric layer 102. The at least one dielectric layer 102 may represent the dielectric layer 640 and/or the dielectric layer 660. A laser process (e.g., laser ablation) and/or a photo etching process may be used to form the plurality of cavities 661 and/or the plurality of cavities 662.

Stage 14 of FIG. 6E, illustrates and describes an example of a state after a mask 670 and a mask 680 are provided on the at least one dielectric layer 102. The mask 670 and/or the mask 680 may include openings. The mask 670 and/or the mask 680 may be a dry film that is exposed and developed.

Stage 15 of FIG. 6E, illustrates and describes an example of a state after a plurality of interconnects 125 and/or the plurality of interconnects 123 are formed and a plurality of interconnects 672 are formed. A plating process may be used to form the plurality of interconnects 123, the plurality of interconnects 125 and the plurality of interconnects 672.

Stage 16 of FIG. 6F, illustrates and describes an example of a state after the mask 670 and the mask 680 are removed.

Stage 17 of FIG. 16F, illustrates and describes an example of a state after the solder resist layer 107 and the solder resist layer 109 are formed and provided on the substrate.

### Exemplary Electronic Devices

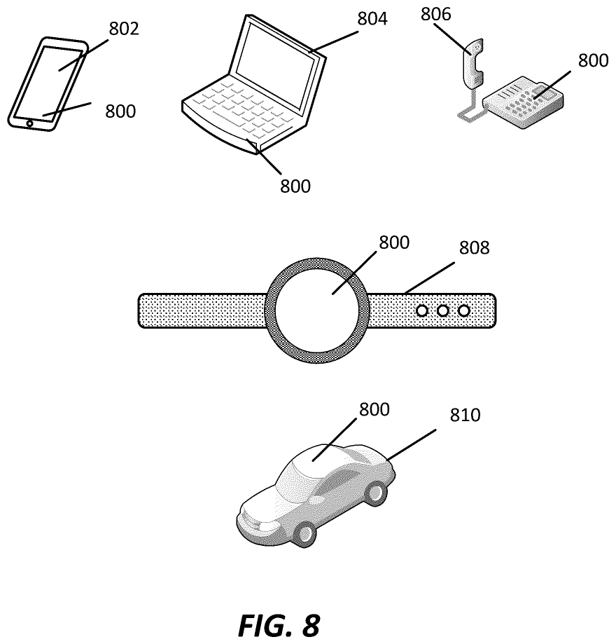

FIG. 8 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 802, a laptop computer device 804, a fixed location terminal device 806, a wearable device 808, or automotive vehicle 810 may include a device 800 as described herein. The device 800 may be, for example, any of the devices and/or integrated circuit (IC) packages described herein. The devices 802, 804, 806 and 808 and the vehicle 810 illustrated in FIG. 8 are merely exemplary. Other electronic devices may also feature the device 800 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-5, 6A-6F, and/or 7-8 may be rearranged and/or combined into a single component, process, feature or function or embodied in several components, processes, or functions. Additional elements, components, processes, and/or functions may also be added without departing from the disclosure. It should also be noted FIGS. 1-5, 6A-6F, and/or 7-8 and its corresponding description in the present disclosure is not limited to dies and/or ICs. In some implementations, FIGS. 1-5, 6A-6F, and/or 7-8 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. A first component that is “located” in a second component may mean that the first component is “partially located” in the second component or “completely located” in the second component. A first component that is “embedded” in a second component may mean that the first component is “partially embedded” in the second component or “completely embedded” in the second component. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

Aspect 1: A substrate comprising a core layer comprising a cavity; a passive device located at least partially in the cavity of the core layer, wherein the passive device comprises: a first plurality of pad interconnects configured to provide at least one electrical path for power; and a second plurality of pad interconnects configured to provide at least one electrical path for ground; at least one dielectric layer coupled to the core layer; and a plurality of interconnects located at least partially in the at least one dielectric layer.

Aspect 2: The substrate of aspect 1, wherein pad interconnects from the first plurality of pad interconnects comprises a first width; and wherein pad interconnects from the second plurality of pad interconnects comprises a second width that is different from the first width.

Aspect 3: The substrate of aspect 2, wherein the second width is greater than the first width.

Aspect 4: The substrate of aspects 1 through 3, wherein the first plurality of pad interconnects are arranged in an alternating manner with the second plurality of pad interconnects.

Aspect 5: The substrate of aspect 4, wherein a first row of pad interconnects comprises a first pad interconnect from the first plurality of pad interconnects; a first pad interconnect from the second plurality of pad interconnects; a second pad interconnect from the first plurality of pad interconnects; and a second pad interconnect from the second plurality of pad interconnects.

Aspect 6: The substrate of aspect 5, wherein a second row of pad interconnects comprises a third pad interconnect from the second plurality of pad interconnects; a third pad interconnect from the first plurality of pad interconnects; a fourth pad interconnect from the second plurality of pad interconnects; and a fourth pad interconnect from the first plurality of pad interconnects.

Aspect 7: The substrate of aspect 5, further comprising a first via interconnect is coupled to and touching the first pad interconnect from the first plurality of pad interconnects; and a second via interconnect is coupled to and touching the second pad interconnect from the first plurality of pad interconnects.

Aspect 8: The substrate of aspect 5, wherein the first pad interconnect and the second pad interconnect from the second plurality of pad interconnects are free of direct touching from a via interconnect.

Aspect 9: The substrate of aspects 1 through 8, wherein the passive device includes a deep trench capacitor.

Aspect 10: The substrate of aspects 1 through 9, wherein the substrate is implemented in a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 11: A package comprising an integrated device; and a substrate coupled to the integrated device through a plurality of solder interconnects, wherein the substrate comprises a core layer comprising a cavity; a passive device located at least partially in the cavity of the core layer, wherein the passive device comprises a first plurality of pad interconnects configured to provide at least one electrical path for power; and a second plurality of pad interconnects configured to provide at least one electrical path for ground; at least one dielectric layer coupled to the core layer; and a plurality of interconnects located at least partially in the at least one dielectric layer.

Aspect 12: The package of aspect 11, wherein pad interconnects from the first plurality of pad interconnects comprises a first width; and wherein pad interconnects from the second plurality of pad interconnects comprises a second width that is different from the first width.

Aspect 13: The package of aspect 12, wherein the second width is greater than the first width.

Aspect 14: The package of aspects 11 through 13, wherein the first plurality of pad interconnects are arranged in an alternating manner with the second plurality of pad interconnects.

Aspect 15: The package of aspect 14, wherein a first row of pad interconnects comprises a first pad interconnect from the first plurality of pad interconnects; a first pad interconnect from the second plurality of pad interconnects; a second pad interconnect from the first plurality of pad interconnects; and a second pad interconnect from the second plurality of pad interconnects.

Aspect 16: The package of aspect 15, wherein a second row of pad interconnects comprises a third pad interconnect from the second plurality of pad interconnects; a third pad interconnect from the first plurality of pad interconnects; a fourth pad interconnect from the second plurality of pad interconnects; and a fourth pad interconnect from the first plurality of pad interconnects.

Aspect 17: The package of aspect 15, wherein the substrate further comprises a first via interconnect is coupled to and touching the first pad interconnect from the first plurality of pad interconnects; and a second via interconnect is coupled to and touching the second pad interconnect from the first plurality of pad interconnects.

Aspect 18: The package of aspect 15, wherein the first pad interconnect and the second pad interconnect from the second plurality of pad interconnects are free of direct touching from a via interconnect.

Aspect 19: The package of aspects 11 through 18, wherein the passive device includes a deep trench capacitor.

Aspect 20: The package of aspects 11 through 19, wherein the package is implemented in a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A substrate comprising:
a core layer comprising a cavity;
a passive device located at least partially in the cavity of the core layer, wherein the passive device comprises:
a first plurality of pad interconnects configured to provide at least one electrical path for power; and
a second plurality of pad interconnects configured to provide at least one electrical path for ground;
at least one dielectric layer coupled to the core layer; and
a plurality of interconnects located at least partially in the at least one dielectric layer.

2. The substrate of claim 1,
wherein pad interconnects from the first plurality of pad interconnects comprises a first width; and
wherein pad interconnects from the second plurality of pad interconnects comprises a second width that is different from the first width.

3. The substrate of claim 2, wherein the second width is greater than the first width.

4. The substrate of claim 1, wherein the first plurality of pad interconnects are arranged in an alternating manner with the second plurality of pad interconnects.

5. The substrate of claim 4, wherein a first row of pad interconnects comprises:
a first pad interconnect from the first plurality of pad interconnects;
a first pad interconnect from the second plurality of pad interconnects;
a second pad interconnect from the first plurality of pad interconnects; and
a second pad interconnect from the second plurality of pad interconnects.

6. The substrate of claim 5, wherein a second row of pad interconnects comprises:
a third pad interconnect from the second plurality of pad interconnects;
a third pad interconnect from the first plurality of pad interconnects;
a fourth pad interconnect from the second plurality of pad interconnects; and
a fourth pad interconnect from the first plurality of pad interconnects.

7. The substrate of claim 5, further comprising:
a first via interconnect is coupled to and touching the first pad interconnect from the first plurality of pad interconnects; and
a second via interconnect is coupled to and touching the second pad interconnect from the first plurality of pad interconnects.

8. The substrate of claim 5, wherein the first pad interconnect and the second pad interconnect from the second plurality of pad interconnects are free of direct touching from a via interconnect.

9. The substrate of claim 1, wherein the passive device includes a deep trench capacitor.

10. The substrate of claim 1, wherein the substrate is implemented in a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

11. A package comprising:
an integrated device; and
a substrate coupled to the integrated device through a plurality of solder interconnects, wherein the substrate comprises:
a core layer comprising a cavity;
a passive device located at least partially in the cavity of the core layer, wherein the passive device comprises:
a first plurality of pad interconnects configured to provide at least one electrical path for power; and
a second plurality of pad interconnects configured to provide at least one electrical path for ground;
at least one dielectric layer coupled to the core layer; and
a plurality of interconnects located at least partially in the at least one dielectric layer.

12. The package of claim 11,
wherein pad interconnects from the first plurality of pad interconnects comprises a first width; and
wherein pad interconnects from the second plurality of pad interconnects comprises a second width that is different from the first width.

13. The package of claim 12, wherein the second width is greater than the first width.

14. The package of claim 11, wherein the first plurality of pad interconnects are arranged in an alternating manner with the second plurality of pad interconnects.

15. The package of claim 14, wherein a first row of pad interconnects comprises:
a first pad interconnect from the first plurality of pad interconnects;
a first pad interconnect from the second plurality of pad interconnects;
a second pad interconnect from the first plurality of pad interconnects; and
a second pad interconnect from the second plurality of pad interconnects.

16. The package of claim 15, wherein a second row of pad interconnects comprises:
a third pad interconnect from the second plurality of pad interconnects;
a third pad interconnect from the first plurality of pad interconnects;
a fourth pad interconnect from the second plurality of pad interconnects; and
a fourth pad interconnect from the first plurality of pad interconnects.

17. The package of claim 15, wherein the substrate further comprises:
a first via interconnect is coupled to and touching the first pad interconnect from the first plurality of pad interconnects; and
a second via interconnect is coupled to and touching the second pad interconnect from the first plurality of pad interconnects.

18. The package of claim 15, wherein the first pad interconnect and the second pad interconnect from the second plurality of pad interconnects are free of direct touching from a via interconnect.

19. The package of claim 11, wherein the passive device includes a deep trench capacitor.

20. The package of claim 11, wherein the package is implemented in a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.
